(19) United States
(12) Patent Application Publication
(10) Pub. No.: US 2025/0233113 A1
(43) Pub. Date: Jul. 17, 2025

(54) PACKAGE STRUCTURE AND METHOD FOR FORMING THE SAME

(71) Applicant: Taiwan Semiconductor Manufacturing Company, Ltd., Hsinchu (TW)

(72) Inventors: Wei-Ting CHEN, Tainan City (TW); Chung-Hao TSAI, Changhua County (TW); Ching-Ho CHIN, Taoyuan City (TW); Chen-Hua YU, Hsinchu City (TW)

(21) Appl. No.: 18/413,276

(22) Filed: Jan. 16, 2024

(51) Int. Cl. H01L 25/065; H01L 23/00; H01L 23/48; H01L 23/522; H01L 23/538; H01L 29/06; H01L 29/417; H01L 29/423; H01L 29/775; H01L 29/786; H10B 80/00

(52) U.S. Cl. CPC H01L 25/0657; H01L 23/481; H01L 23/5226; H01L 23/5384; H01L 24/08; H01L 24/80; H10B 80/00; H10D 30/43; H10D 30/6735; H10D 30/6757; H10D 62/121; H10D 64/258; H01L 2224/08225; H01L 2224/80895; H01L 2224/80896

(57) ABSTRACT

A package structure and method for forming the same are provided. The package structure includes a first die formed over an interposer, and the first die includes a first logic device, a first memory device formed over the first logic device, and a hybrid bonding structure between the first logic device and the first memory device. The package structure includes a second die adjacent to the first die. The second die includes a second logic device, and a second memory device formed over the second logic device; and a package layer surrounding the first die and the second die. A portion of the interposer is covered by the package layer.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (PoP), have begun to be developed, in which a top package with a device die is bonded to a bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 shows perspective view of a semiconductor structure, in accordance with some embodiments of the disclosure.

FIGS. 2A to 2C illustrate cross-sectional representations of various stages of manufacturing the semiconductor structure shown along line A-A′ in FIG. 1, in accordance with some embodiments.

FIGS. 3A-3H show cross-sectional representations of various stages of forming a package structure, in accordance with some embodiments of the disclosure.

FIG. 3H′ shows a cross-sectional representation of a package structure, in accordance with some embodiments of the disclosure.

FIGS. 4A-4F show cross-sectional representations of various stages of forming a package structure, in accordance with some embodiments of the disclosure.

FIG. 5 shows a cross-sectional representation of a package structure, in accordance with some embodiments of the disclosure.

FIG. 6 shows a cross-sectional representation of a package structure, in accordance with some embodiments of the disclosure.

FIG. 7 shows a cross-sectional representation of a package structure, in accordance with some embodiments of the disclosure.

FIG. 8 shows a cross-sectional representation of a package structure, in accordance with some embodiments of the disclosure.

FIG. 9 shows a cross-sectional representation of a package structure, in accordance with some embodiments of the disclosure.

FIG. 10 shows a cross-sectional representation of a package structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes an electrical die with a logic device (such as GAA device) and a memory device stacked vertically. The electrical die includes a substrate, and a logic device formed on the substrate, and the front-side interconnect structure and the back-side interconnect structure formed on opposite sidewall surfaces of the substrate. The memory device is formed on the electrical die with logic device. Since the memory device is vertically formed on the electrical die, the passage of the electrical signals is reduced and the transmission speed of the electrical signals is improved. When the signal path is reduced, the driving power for the package structure can be reduced. Therefore, the power efficiency of the package structure is increased.

Furthermore, since the optical device is formed below the login device and the memory device, and the passage of the electrical signals and the optical signals are reduced and the transmission speed of the electrical signals and the optical signals are improved.

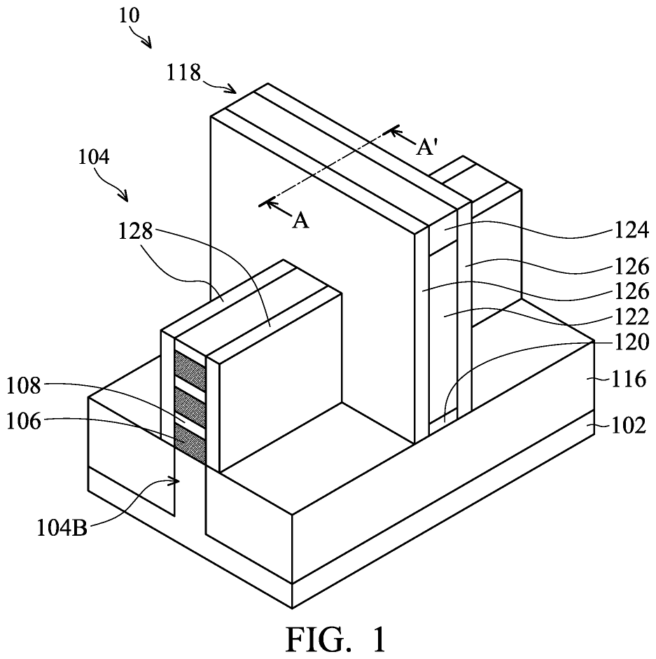

FIG. 1 shows perspective view of a semiconductor structure 10, in accordance with some embodiments of the disclosure. The semiconductor structure 10 is a logic device.

Referring to FIG. 1, a substrate 102 is provided. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 104B and the semiconductor material stack of the first semiconductor material layers 106 and the second semiconductor material layers 108.

After the fin structure 104 is formed, an isolation structure 116 is formed

around the fin structure 104. After the isolation structure 116 is formed, a dummy gate structure 118 is formed across the fin structure 104 and extends over the isolation structure 116. The dummy gate structure 118 may be used to define the source/drain regions and the channel regions of the resulting semiconductor structure 10.

In some embodiments, the dummy gate structure 118 includes a dummy gate dielectric layer 120 and a dummy gate electrode layer 122. In some embodiments, the dummy gate dielectric layer 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic vapor deposition (ALD), physical vapor deposition (PVD), another suitable method, or a combination thereof.

In some embodiments, the dummy gate electrode layer 122 includes conductive material. In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

In some embodiments, a hard mask layer 124 is formed over the dummy gate structure 118. In some embodiments, the hard mask layer 124 includes multiple layers, such as an oxide layer and a nitride layer. In some embodiments, the oxide layer is silicon oxide, and the nitride layer is silicon nitride.

After the dummy gate structure 118 is formed, gate spacers 126 are formed along and covering opposite sidewall surfaces of the dummy gate structure 118 and fin spacers 128 are formed along and covering opposite sidewall surfaces of the source/drain (S/D) regions of the fin structure 104, in accordance with some embodiments. The source/drain (S/D) structure or region(s) may refer to a source or a drain, individually or collectively dependent upon the context.

The gate spacers 126 may be configured to separate source/drain (S/D) structures from the dummy gate structure 118 and support the dummy gate structure 118, and the fin spacers 128 may be configured to constrain a lateral growth of subsequently formed source/drain (S/D) structure and support the fin structure 104.

In some embodiments, the gate spacers 126 and the fin spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacers 126 and the fin spacers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

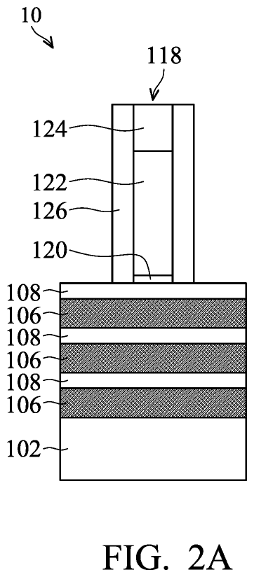

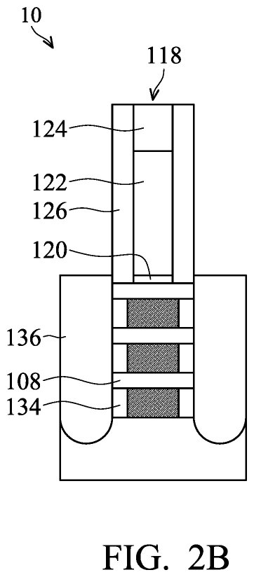

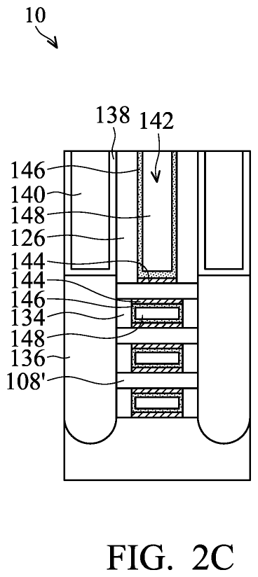

FIGS. 2A to 2C illustrate cross-sectional representations of various stages of manufacturing the semiconductor structure 10 shown along line A-A′ in FIG. 1, in accordance with some embodiments.

As shown in FIG. 2A, the dummy gate structure 118 is formed over the fin structure 104. The gate spacers 126 are formed on sidewall surfaces of the dummy gate structure 118. The dummy gate structure 118 includes the dummy gate dielectric layer 120 and the dummy gate electrode layer 122.

Next, as shown in FIG. 2B, the source/drain (S/D) regions of the fin structure 104 are recessed to form source/drain (S/D) recesses (not shown), in accordance with some embodiments. More specifically, the first semiconductor material layers 106 and the second semiconductor material layers 108 not covered by the dummy gate structures 118 and the gate spacers 126 are removed.

After the source/drain (S/D) recesses are formed, the first semiconductor material layers 106 exposed by the source/drain (S/D) recesses are laterally recessed to form notches (not shown), and the inner spacers 134 are formed in the notches between the second semiconductor material layers 108, in accordance with some embodiments.

The inner spacers 134 are configured to separate the source/drain (S/D) structures and the gate structures formed in subsequent manufacturing processes in accordance with some embodiments. In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 134 are formed by a deposition process, such as chemical vapor deposition (CVD) process, atomic layer deposition (ALD) process, another applicable process, or a combination thereof.

After the inner spacers 134 are formed, the source/drain (S/D) structures 136 are formed in the S/D recesses. In some embodiments, the S/D structures 136 are formed using an epitaxial growth process, such as molecular beam epitaxy (MBE), Metal-organic chemical vapor deposition (MOCVD), vapor-phase epitaxy (VPE), other applicable epitaxial growth process, or a combination thereof. In some embodiments, the S/D structures 136 are made of any applicable material, such as Ge, Si, GaAs, AlGaAs, SiGe, GaAsP, SiP, SiC, SiCP, or a combination thereof.

In some embodiments, the S/D structures 136 are in-situ doped during the epitaxial growth process. For example, the S/D structures 136 may be the epitaxially grown SiGe doped with boron (B). For example, the S/D structures 136 may be the epitaxially grown Si doped with carbon to form silicon: carbon (Si:C) source/drain features, phosphorous to form silicon: phosphor (Si:P) source/drain features, or both carbon and phosphorous to form silicon carbon phosphor (SiCP) source/drain features. In some embodiments, the S/D structures 136 are doped in one or more implantation processes after the epitaxial growth process.

Afterwards, as shown in FIG. 2C, after the S/D structures 136 are formed, a contact etch stop layer (CESL) 138 is conformally formed to cover the S/D structures 136 and an interlayer dielectric (ILD) layer 140 is formed over the contact etch stop layers 138, in accordance with some embodiments.

In some embodiments, the contact etch stop layer 138 includes a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

The dummy gate structure 118 is replaced by a gate structure 142, in accordance with some embodiments. More specifically, the dummy gate structure 118 and the first semiconductor material layers 106 are removed to form nanostructures 108′ with the second semiconductor material layers 108, in accordance with some embodiments. The S/D structure 136 is attached to the nanostructures 108′.

The gate structures 142 wrap around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layer 144 is an oxide layer formed around the nanostructures 108′ and on the top of the base fin structure 104B. In some embodiments, the interfacial layer 144 is formed by performing a thermal process.

In some embodiments, the gate dielectric layers 146 are formed over the interfacial layer 144, so that the nanostructures 108′ are surrounded by (e.g. wrapped in) the gate dielectric layer 146. In addition, the gate dielectric layer 146 also covers the sidewalls of the gate spacers 126 and the inner spacers 134 in accordance with some embodiments. In some embodiments, the gate dielectric layer 146 includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layer 146 is formed using chemical vapor deposition (CVD), atomic layer deposition (ALD), another applicable method, or a combination thereof.

In some embodiments, the gate electrode layer 148 is formed on the gate dielectric layer 146. In some embodiments, the gate electrode layer 148 includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 148 is formed using chemical vapor deposition (CVD), atomic layer deposition (ALD), electroplating, another applicable method, or a combination thereof. Other conductive layers, such as work function metal layers, may also be formed in the gate structure 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

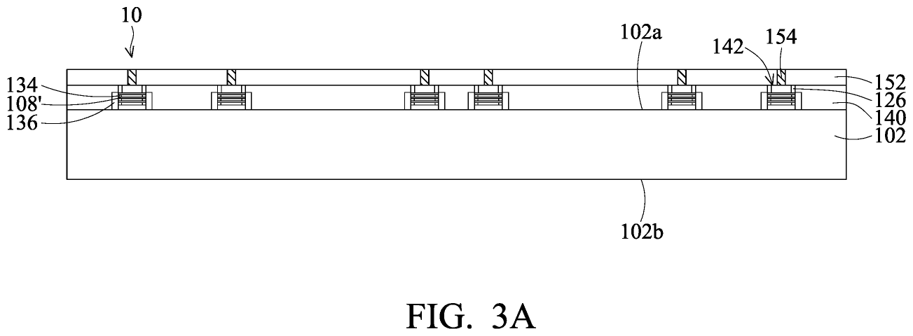

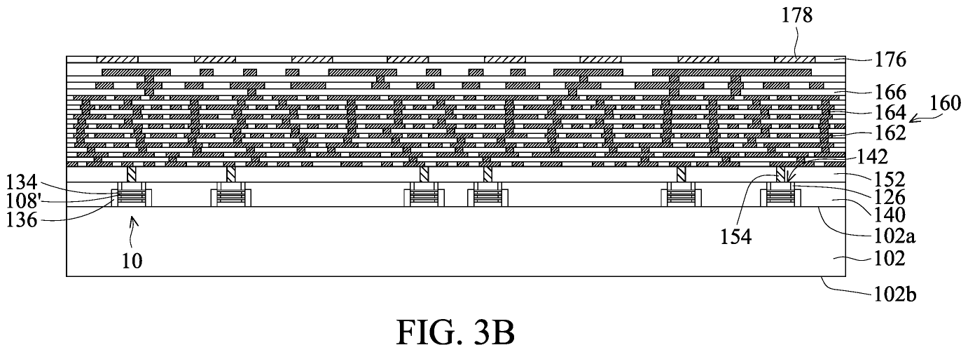

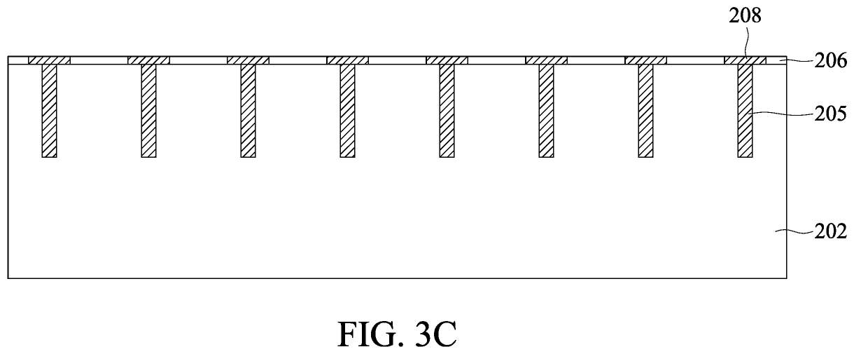

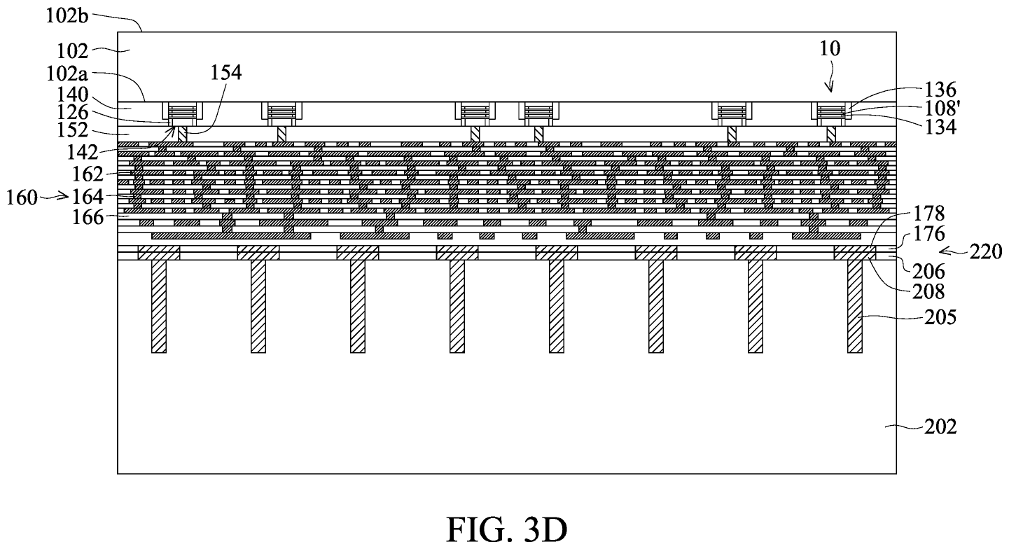

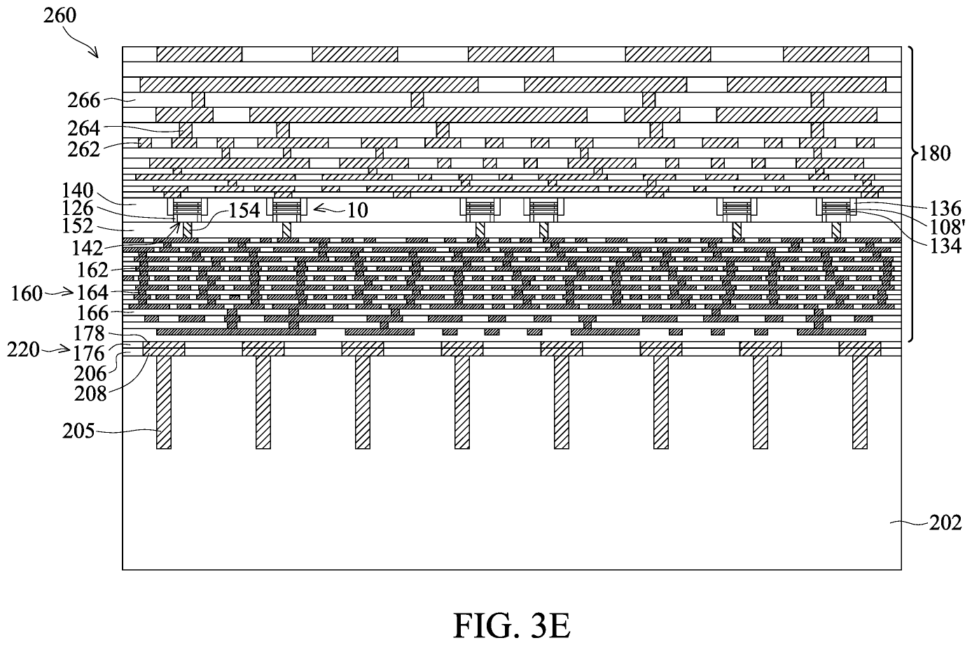

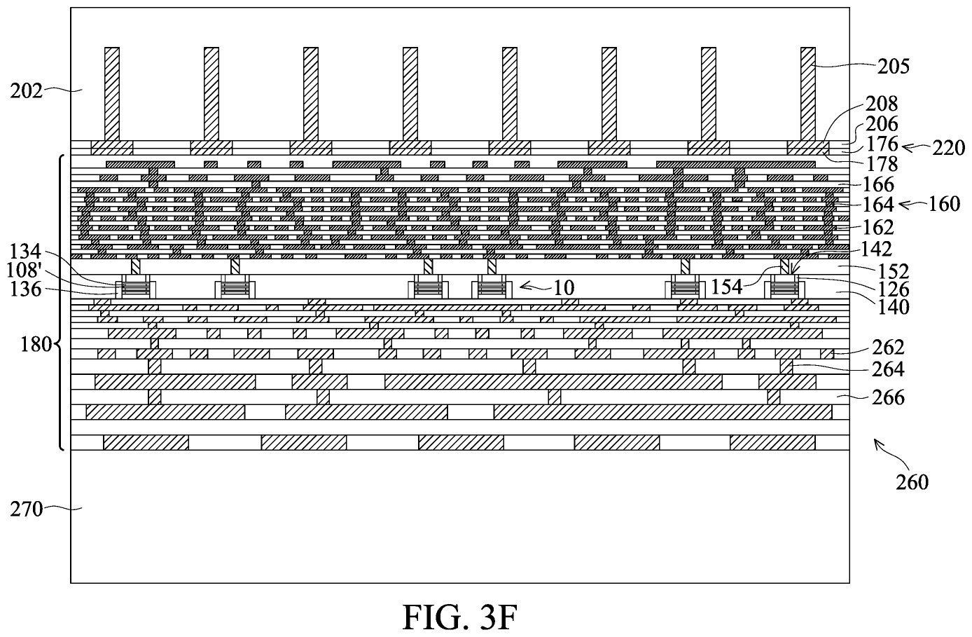

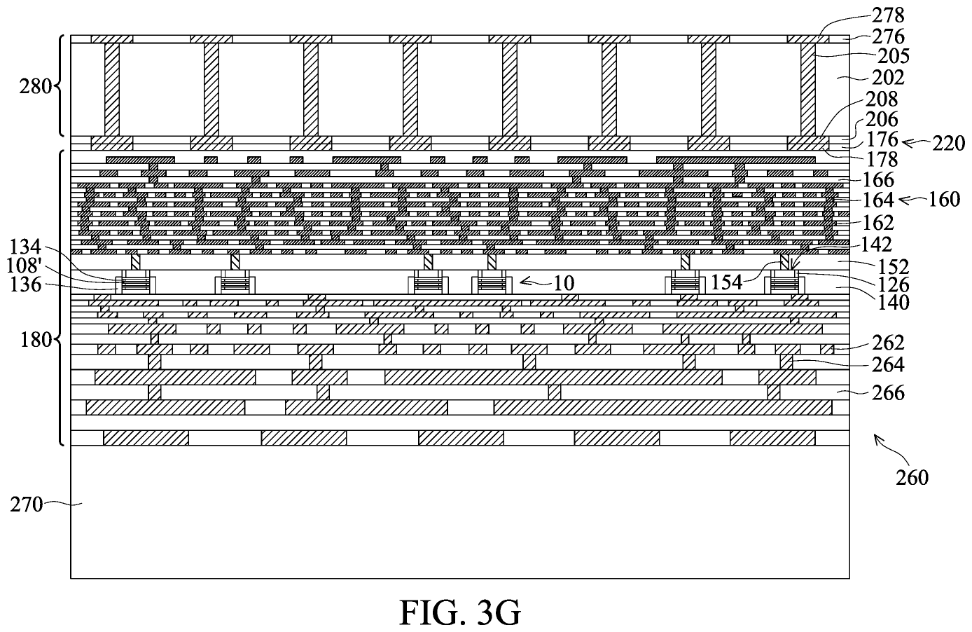

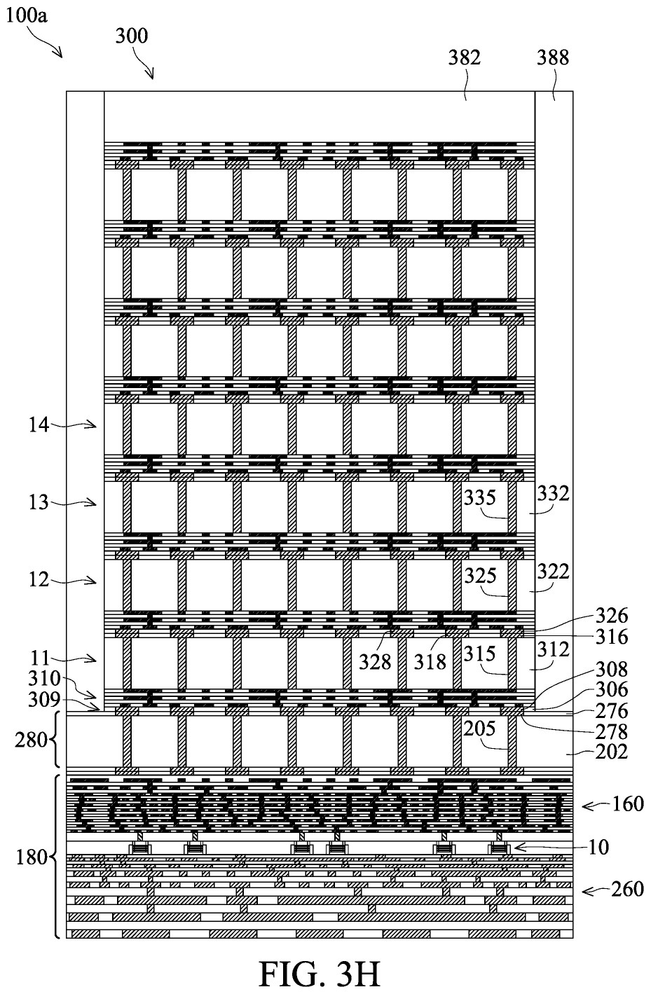

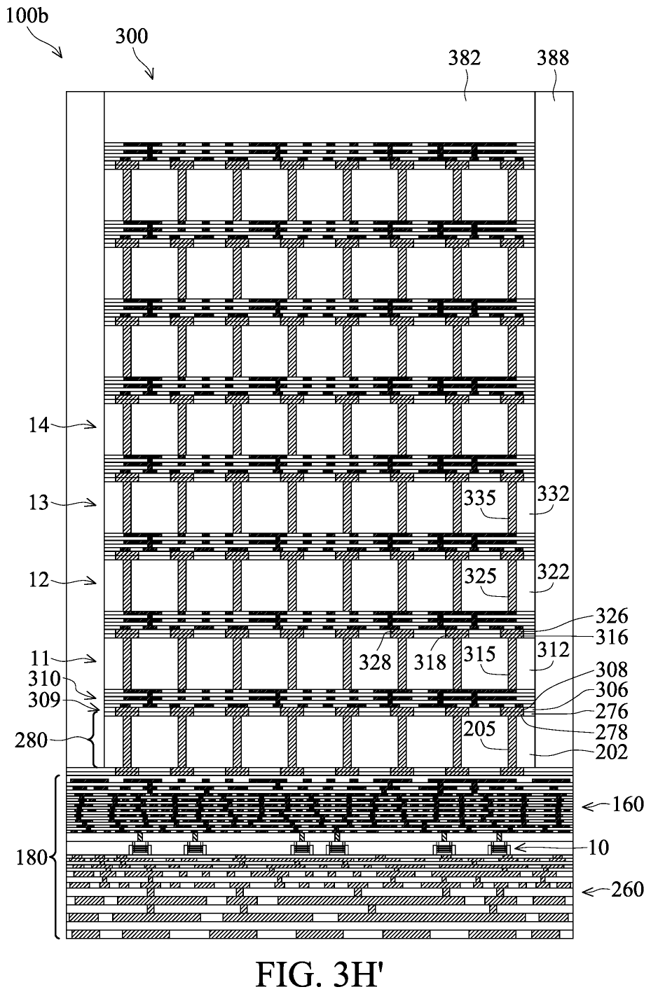

FIGS. 3A-3H show cross-sectional representations of various stages of forming a package structure 100a, in accordance with some embodiments of the disclosure.

As shown in FIG. 3A, the substrate 102 has a front-side surface 102a and a back-side surface 102b. The semiconductor structures 10 are formed over the front-side surface 102a of the substrate 102. Some elements of the semiconductor structures 10 are not shown in detail for clarity, the detail structure of the semiconductor structures 10 can refer to FIG. 2C. The number of semiconductor structures 10 can be adjusted according to their actual application.

A dielectric layer 152 is formed over the ILD layer 140, and a contact structure 154 is formed in the dielectric layer 152. The contact structure 154 is formed over and in direct contact with the gate electrode layer 148 of the gate structure 142.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes

The contact structure 154 includes a conductive material including aluminum (Al), copper (Cu), tungsten (W), titanium (Ti), tantalum (Ta), titanium nitride (TiN), cobalt (Co), tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the contact structure 154 may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition process.

Next, as shown in FIG. 3B, an interconnect structure 160 is formed over the dielectric layer 152, in accordance with some embodiments of the disclosure. The interconnect structure 160 is a front-side interconnect structure. The interconnect structure 160 is formed in a back-end-of-line (BEOL). The interconnect structure 160 may be used as a redistribution (RDL) structure for routing.

The interconnect structure 160 includes conductive layers 162 and contact plugs 164 and dielectric layers 166. The conductive layers 162 and contact plugs 164 are embedded in the dielectric layer 166. In some embodiments, the conductive layers 162 and the contact plugs 164 are made of conductive materials, such as copper (Cu), copper alloy, aluminum (Al), aluminum alloys, combinations thereof or another applicable material. In some embodiments, the conductive layers 162 and the contact plugs 164 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process. The dielectric layer 166 may include multilayers made of multiple dielectric materials, such as silicon oxide, silicon nitride, silicon oxynitride, and/or other applicable dielectric materials. The dielectric layer 166 may be formed by chemical vapor deposition (CVD), physical vapor deposition, (PVD), atomic layer deposition (ALD), or other applicable processes.

A bonding layer 176 is formed on the dielectric layers 166, and conductive layers 178 are formed in the bonding layer 176. In some embodiments, the bonding layer 176 and the dielectric layer 166 are made of the same material. In some other embodiments, the bonding layer 176 and the dielectric layer 166 are made of different materials. In some embodiments, the bonding layer 176 is made of silicon, silicon oxide, or the like. In some embodiments, the bonding layer 176 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

In some embodiments, the conductive pads 178 are made of conductive materials, such as such as copper (Cu), copper alloy, aluminum (Al), aluminum alloys, combinations thereof or another applicable material. In some embodiments, the conductive pads 178 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

Afterwards, as shown in FIG. 3C, a substrate 202 is provided. The substrate 202 may be a semiconductor wafer such as a silicon wafer. Alternatively or additionally, the substrate 202 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The through-substrate via (TSV) structures 205 are formed in the substrate 202. The TSV structures 205 may be referred to as through-silicon vias. A bonding layer 206 is formed on the substrate 202, and conductive pads 208 are formed in the bonding layer 206.

In some embodiments, the TSV structures 205 are formed by forming a number of trenches (not shown) which extend from the front surface of the substrate 202. Afterwards, a barrier layer (not shown) is filled into each of the trenches, and the conductive materials are formed on the barrier layer and in each of the trenches to form the TSV structures 205.

In some embodiments, the bonding layer 206 is made of silicon, silicon oxide, or the like. In some embodiments, the bonding layer 206 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

In some embodiments, the conductive pads 208 are made of conductive materials, such as such as copper (Cu), copper alloy, aluminum (Al), aluminum alloys, combinations thereof or another applicable material. In some embodiments, the conductive pads 208 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

Next, as shown in FIG. 3D, the structure as shown in FIG. 3A is flipped and attached to the substrate 202, in accordance with some embodiments of the disclosure. The bonding layer 206 is bonded to the bonding layer 176, and the conductive pads 208 are bonded to the conductive pads 178 to form a hybrid bonding structure 220.

The hybrid bonding involves at least two types of bonding, including metal-to-metal bonding and non-metal-to-non-metal bonding. As shown in FIG. 3D, the bonding structure 220 is formed between the substrate 102 and the substrate 202. The bonding structure 220 is a hybrid bonding structure which includes the conductive pads 178, 208 bonded by metal-to-metal bonding and bonding layers 176, 206 bonded by non-metal-to-non-metal bonding. The bonding layer 176 and the bonding layer 206 are hybrid bonded together by the application of pressure and heat.

Afterwards, as shown in FIG. 3E, the substrate 102 is removed, and an interconnect structure 260 is formed on the back-side 102b of the substrate 102. As a result, an electrical die 180 is formed. The electrical die 180 includes the semiconductor device 10, and the interconnect structure 160 and the interconnect structure 260 formed on opposite sidewall surfaces of the semiconductor device 10. In some other embodiments, the substrate 102 is not completely removed, and a remaining substrate 102 has a thickness in a range from about 50 nm to about 100 nm. The TSV structure may be formed in the remaining substrate 102 to connect the interconnect structure 260.

The interconnect structure 260 is a back-side interconnect structure. The interconnect structure 260 may be used as a redistribution (RDL) structure for routing. In some embodiments, the interconnect structure 260 is the back-side power delivery network (BSPDN).

The interconnect structure 260 includes conductive layers 262 and contact plugs 264 and dielectric layers 266. The conductive layers 262 and contact plugs 264 are embedded in the dielectric layer 266. In some embodiments, the thickness of the conductive layers 262 of the interconnect structure 260 is greater than the thickness of the conductive layers 162 of the interconnect structure 160 for help the back-side (power) transferring (distribution).

In some embodiments, the conductive layers 262 and the contact plugs 264 are made of conductive materials, such as copper (Cu), copper alloy, aluminum (Al), aluminum alloys, combinations thereof or another applicable material. In some embodiments, the conductive layers 262 and the contact plugs 264 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The dielectric layer 266 may include multilayers made of multiple dielectric materials, such as silicon oxide, silicon nitride, silicon oxynitride, and/or other applicable dielectric materials. The dielectric layer 266 may be formed by chemical vapor deposition (CVD), physical vapor deposition, (PVD), atomic layer deposition (ALD), or other applicable processes.

Next, as shown in FIG. 3F, the structure as shown in FIG. 3E is flipped and attached to a carrier substrate 270, in accordance with some embodiments of the disclosure.

In some embodiments, the dielectric layer 266 is attached to the carrier substrate 270 by an adhesive layer (not shown). The adhesive layer is used as a temporary adhesive layer. The adhesive layer may be glue or a tape. In some embodiments, the adhesive layer is photosensitive and is easily detached from the carrier substrate 270 by light irradiation. For example, shining ultra-violet (UV) light or laser light on the carrier substrate 270 is used to detach the adhesive layer. In some other embodiments, the adhesive layer is heat-sensitive and is easily detached from the carrier substrate 270 when it is exposed to heat.

The carrier substrate 270 is configured to provide temporary mechanical and structural support during subsequent processing steps. The carrier substrate 270 includes glass, silicon oxide, aluminum oxide, metal, a combination thereof, and/or the like.

Afterwards, as shown in FIG. 3G, the substrate 202 is thinned by using the carrier substrate 270 as support until the TSV structures 205 are exposed, in accordance with some embodiments of the disclosure. Next, a bonding layer 276 is formed on the substrate 202, and conductive pads 278 are formed in the bonding layer 276. The conductive pads 278 are formed on and in direct contact with the TSV structures 205. The conductive pads 278 are electrically connected to the conductive pads 208 by the TSV structures 205. As a result, an interposer 280 having TSV structures 205 in the substrate 202 is formed.

In some embodiments, the outer sidewall surface of the interposer 280 is substantially aligned with the outer sidewall surface of the interconnect structure 160. In some other embodiments, the outer sidewall surface of the interconnect structure 160 extends beyond the outer sidewall surface of the interposer 280. In other words, the width of the interconnect structure 160 is greater than the width of the interposer 280.

In some embodiments, the passive devices (not shown) are formed in the substrate 202. The passive devices may be capacitors, inductors, resistors, or the like. In some embodiments, the active devices (not shown) are formed in the substrate 202. The active devices may be transistors, diodes, or the like.

Next, as shown in FIG. 3H, a memory device 300 is formed on the substrate 202, in accordance with some embodiments of the disclosure. More specifically, the memory device 300 is formed on the electrical die 180. The memory device 300 is electrically connected to the electrical die 180 by the interposer 280. The memory device 300 and the interconnect structure 260 are formed on opposite sidewall surfaces of the logic device 10.

The memory device includes a number of dies 11, 12, 13, 14 stacked vertically, and a top substrate 382 formed on the topmost die. The dies 11, 12, 13, 14 are bonded together in a hybrid bonding process.

The die 11 includes a substrate 312, and an interconnect structure 310 formed below the substrate 312. The interconnect structure 310 includes a bonding layer 306 and conductive pads 308 embedded in the bonding layer 306. The TSV structures 315 are formed in the substrate 312. A bonding layer 316 is formed on the substrate 312, and the conductive pads 318 are embedded in the bonding layer 316. The bonding layer 306 and the bonding layer 316 are formed on opposite sidewall surfaces of the substrate 312. The die 11 is bonded to the substrate 202 via a hybrid bonding structure 309 by bonding the bonding layer 276 to the bonding layer 306, and bonding the conductive pads 278 to the conductive pads 308.

Next, the die 12 is bonded to the die 11 by a hybrid bonding structure. The die 12 includes a substrate 322, and the TSV structures 325 formed in the substrate 322. A bonding layer 326 is formed below the substrate 322, and the conductive pads 328 are formed in the bonding layer 326. The die 11 is bonded to the die 12 by a hybrid bonding structure. The hybrid bonding structure includes the bonding layer 316 bonded to the bonding layer 326 and the conductive pads 318 bonded to the conductive pads 328.

Next, the die 13 is bonded to the die 12 by a hybrid bonding structure. The die 13 includes a substrate 332, and the TSV structures 335 formed in the substrate 332. The die 13 is bonded to the die 12 by the hybrid bonding structure.

In some embodiments, the dies 11, 12, 13 and 14 are memory dies. The memory dies may include static random access memory (SRAM) devices, dynamic random access memory (DRAM) devices, high bandwidth memory (HBM) or other memory dies. The dies 11, 12, 13 and 14 are sawed from a wafer, and may be a “known-good-die”.

Afterwards, a package layer 388 is formed on the memory device 300. The dies 11, 12, 13 and 14 of the memory device 300 are surrounded by the package layer 388. In addition, the package layer 388 is formed on a portion of the top surface of the substrate 202. The package layer 388 is made of a molding compound material. The molding compound material may include a polymer material, such as an epoxy-based resin with fillers dispersed therein. In some embodiments, a liquid molding compound material is applied over the memory device 300. A thermal process is then used to cure the liquid molding compound material and to transform it into the package layer 388.

In some embodiments, the outer sidewall surface of the interposer 280 extends beyond the outer sidewall surface of the memory device 300. In some other embodiments, the outer sidewall surface of the memory device 300 is aligned with the outer sidewall surface of the interposer 180. In some embodiments, an outer sidewall surface of the first interconnect structure 160 extends beyond an outer sidewall surface of one of the dies 11, 12, 13 and 14 of the memory device 300.

As shown in FIG. 3H, the memory device 300 is formed on the electrical die 180, and the interposer 280 is between the memory device 300 and the electrical die 180. The semiconductor structure 10 (such as logic device) is formed over the substrate 102, and the interconnect structure 160 and the interconnect structure 260 are formed on opposite sidewall surfaces of the semiconductor structure 10 (such as logic device).

The electrical signal of the semiconductor structure 10 can be transferred from the interconnect structure 160 or the interconnect structure 260. Since the signals can be transferred from the semiconductor structure 10 to the front-side and back-side of the substrate 202, the I/O numbers can be increased. As a result, the bandwidth of the package structure 100a can be increased.

Furthermore, since the memory device 300 is vertically formed on the electrical die 180, passage of the electrical signals is reduced and the transmission speed of the electrical signals is improved. When the signal path is reduced, the driving power for the package structure 100a can be reduced. Therefore, the power efficiency of the package structure 100a is increased.

FIG. 3H′ shows a cross-sectional representation of a package structure 100b, in accordance with some embodiments of the disclosure. The package structure 100b is similar to, or the same as, the package structure 100a shown in FIGS. 3A-3H. Processes and materials used to form the semiconductor device structure 100b may be similar to, or the same as, those used to form the semiconductor device structure 100a and a detailed description thereof is not repeated herein.

The difference between FIG. 3H′ and FIG. 3H is that the outer sidewall surface of the interconnect structure 160 extends beyond the outer sidewall surface of the interposer 280. The outer sidewall surface of the electrical die 180 extends beyond the outer sidewall surface of the interposer 280. In other words, the outer sidewall surface of the interposer 280 is substantially aligned with the outer sidewall surface of the memory device 300. The package layer 388 is formed on sidewall surfaces of the interposer 280.

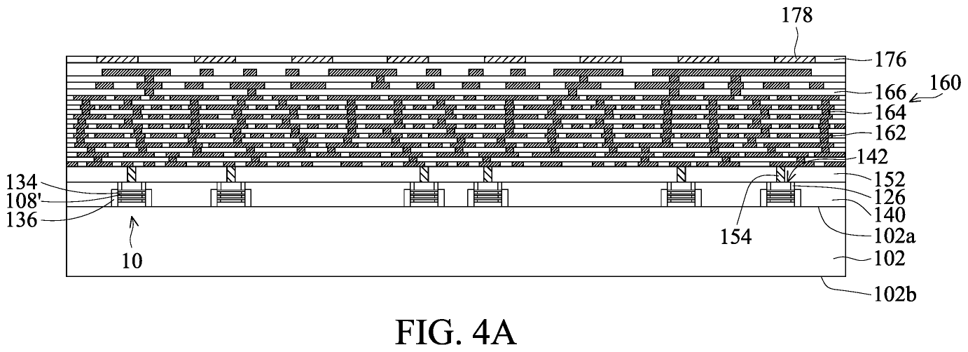

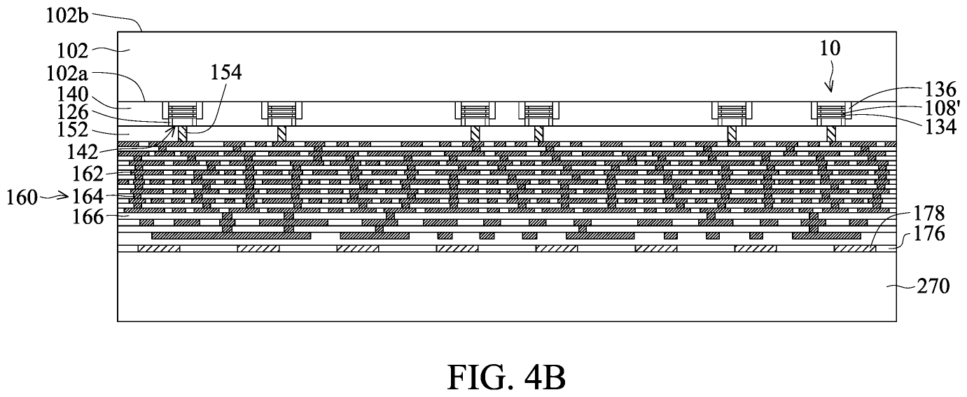

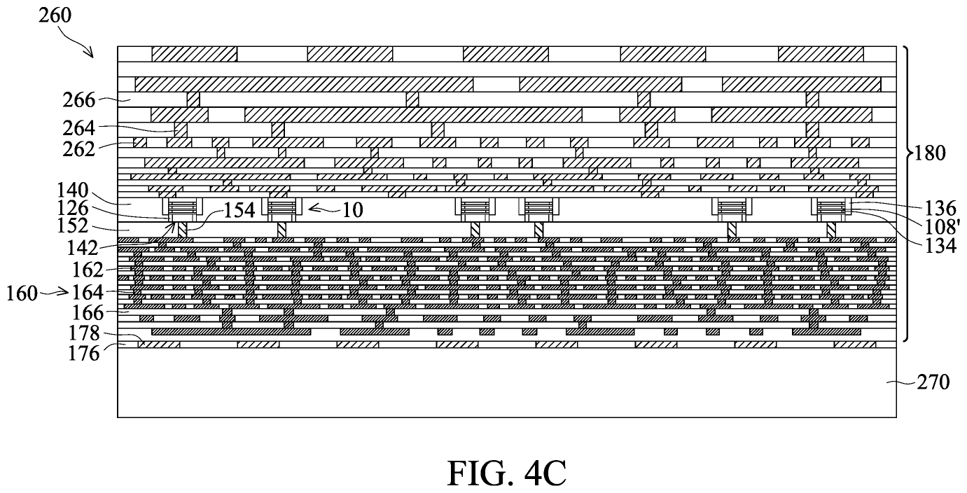

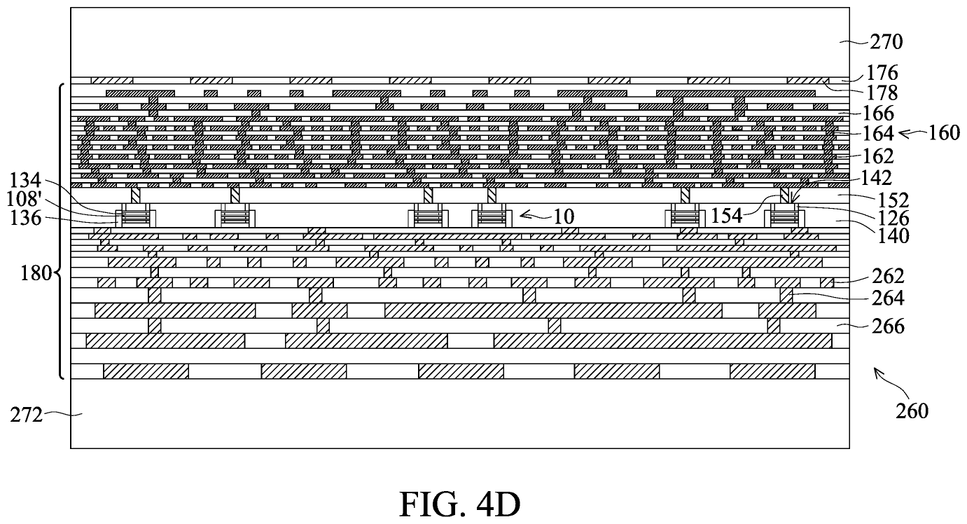

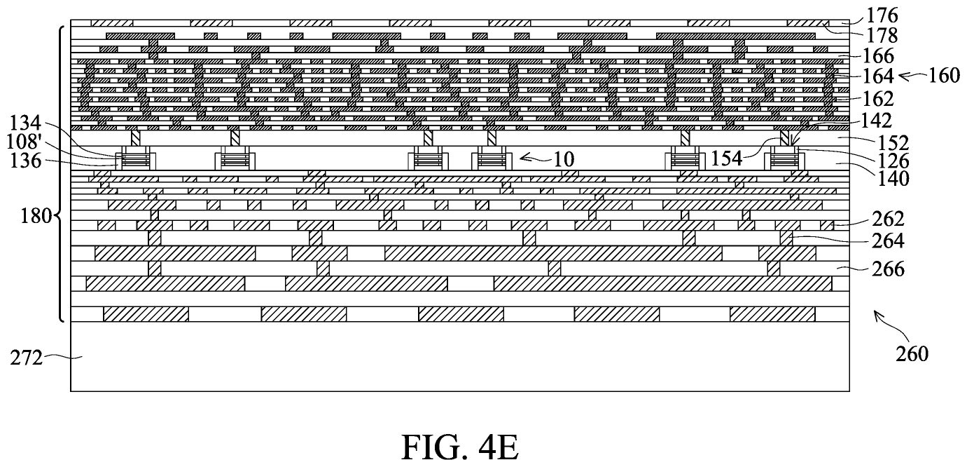

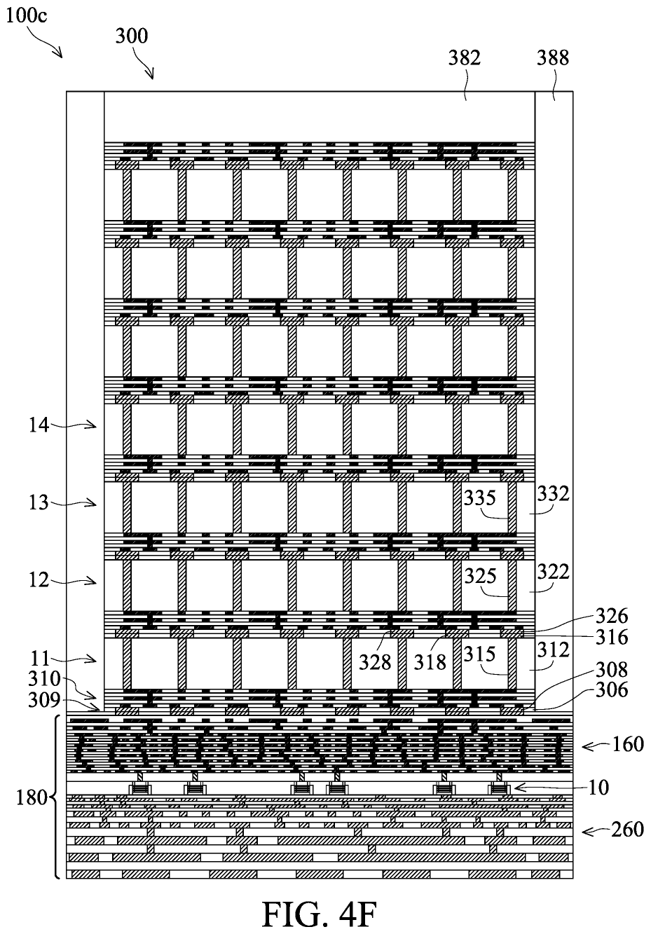

FIGS. 4A-4F show cross-sectional representations of various stages of forming a package structure 100c, in accordance with some embodiments of the disclosure. The package structure 100c is similar to, or the same as, the package structure 100a shown in FIGS. 3A-3H. Processes and materials used to form the semiconductor device structure 100 may be similar to, or the same as, those used to form the semiconductor device structure 100a and a detailed description thereof is not repeated herein.

FIG. 4A is similar to, or the same as FIG. 3B. As shown in FIG. 4A, the substrate 102 has the front-side surface 102a and the back-side surface 102b. The interconnect structure 160 is formed on the front-side 102a of the substrate 102.

Next, as shown in FIG. 4B, the structure as shown in FIG. 4A is flipped and attached to the carrier substrate 270, in accordance with some embodiments of the disclosure. The carrier substrate 270 is configured to provide temporary mechanical and structural support during subsequent processing steps. The carrier substrate 270 includes glass, silicon oxide, aluminum oxide, metal, a combination thereof, and/or the like.

In some embodiments, the bonding layer 176 is attached to the carrier substrate 270 by an adhesive layer (not shown). The adhesive layer is used as a temporary adhesive layer. The adhesive layer may be glue or a tape. In some embodiments, the adhesive layer is photosensitive and is easily detached from the carrier substrate 270 by light irradiation. For example, shining ultra-violet (UV) light or laser light on the carrier substrate 270 is used to detach the adhesive layer. In some other embodiments, the adhesive layer is heat-sensitive and is easily detached from the carrier substrate 270 when it is exposed to heat. The carrier substrate 270 includes glass, silicon oxide, aluminum oxide, metal, a combination thereof, and/or the like.

Afterwards, as shown in FIG. 4C, the substrate 102 is removed, and the interconnect structure 260 is formed on the back-side 102b of the substrate 102. As a result, an electrical die 180 is formed. The electrical die 180 includes the substrate 102, and the semiconductor device 10 formed in the substrate 102, and the interconnect structure 160 and the interconnect structure 260 formed on opposite sidewall surfaces of the substrate 102.

The interconnect structure 260 is a back-side-side interconnect structure. The interconnect structure 260 may be used as a redistribution (RDL) structure for routing. In some embodiments, the interconnect structure 260 is the back-side power delivery network (BSPDN).

The interconnect structure 260 includes conductive layers 262 and contact plugs 264 and dielectric layers 266. The conductive layers 262 and contact plugs 264 are embedded in the dielectric layer 266.

Next, as shown in FIG. 4D, the structure as shown in FIG. 4C is flipped and attached to a carrier substrate 272, in accordance with some embodiments of the disclosure. The carrier substrate 272 is configured to provide temporary mechanical and structural support during subsequent processing steps. The carrier substrate 272 includes glass, silicon oxide, aluminum oxide, metal, a combination thereof, and/or the like.

Afterwards, as shown in FIG. 4E, the carrier substrate 270 is removed to expose the bonding layer 176 and the conductive pads 178, in accordance with some embodiments of the disclosure.

Next, as shown in FIG. 4F, the memory device 300 is bonded to the electrical die 180, in accordance with some embodiments of the disclosure. More specifically, the memory device 300 is directly formed on the electrical die 180 without through any interposer. The memory device 300 is electrically connected to the electrical die 180.

The memory device includes a number of dies 11, 12, 13, 14 stacked vertically, and the top substrate 382 formed on the topmost die. The dies 11, 12, 13, 14 are bonded together in a hybrid bonding process. The number of the dies 11, 12, 13, 14 can be adjusted according to actual application.

The die 11 includes a substrate 312, and the interconnect structure 310 formed below the substrate 312. The interconnect structure 310 includes the bonding layer 306 and conductive pads 308 embedded in the bonding layer 306. The TSV structures 315 are formed in the substrate 312. The bonding layer 316 is formed on the substrate 312, and the conductive pads 318 are embedded in the bonding layer 316. The bonding layer 306 and the bonding layer 316 are formed on opposite sidewall surfaces of the substrate 312. The die 11 is bonded to the substrate 202 by the hybrid bonding structure 309 by bonding the bonding layer 176 to the bonding layer 306, and bonding the conductive pads 178 to the conductive pads 308.

Next, the die 12 is bonded to die 11 by a hybrid bonding structure. The die 13 is bonded to die 12 by a hybrid bonding structure. The hybrid bonding structure includes a metal-to-metal bonding and a non-metal-to-non-metal bonding.

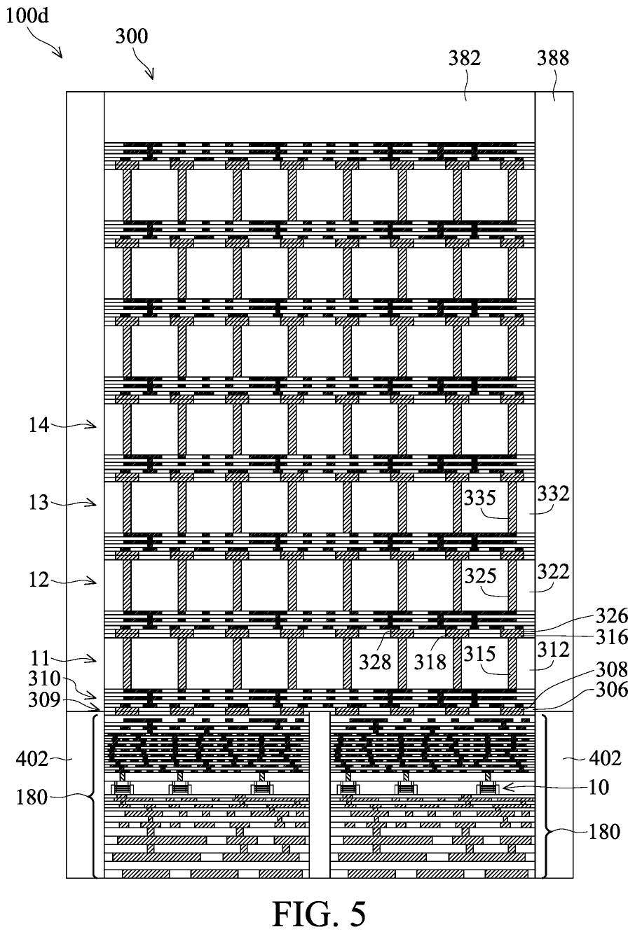

FIG. 5 shows a cross-sectional representation of a package structure 100d, in accordance with some embodiments of the disclosure. The package structure 100d is similar to, or the same as, the package structure 100a shown in FIGS. 3A-3H. Processes and materials used to form the semiconductor device structure 100d may be similar to, or the same as, those used to form the semiconductor device structure 100a and a detailed description thereof is not repeated herein.

As shown in FIG. 5, at least two electrical dies 180 are formed in the substrate 402. In some embodiments, the substrate 402 is a wafer. The electrical dies 180 are embedded in the substrate 402. The width of the electrical die 180 is smaller than the width of the memory device 300. In some embodiments, the function and detail structure of the left electrical die 180 is different form the function and detail structure of the right electrical die 180.

The memory device 300 is bonded to two electrical dies 180. The package layer 388 covers the memory device 300 and the substrate 402. The number of electrical dies 180 is not limited to two, and the number of electrical dies 180 can be adjusted according to their actual application.

The memory device 300 is bonded to the electrical dies 180 by the hybrid bonding structure. The hybrid bonding structure includes metal-to-metal bonding and non-metal-to non-metal bonding. The metal-to-metal bonding includes the conductive pads 178 bonded to conductive pads 308. The non-metal-to non-metal bonding includes bonding layer 176 bonded to the bonding layer 306.

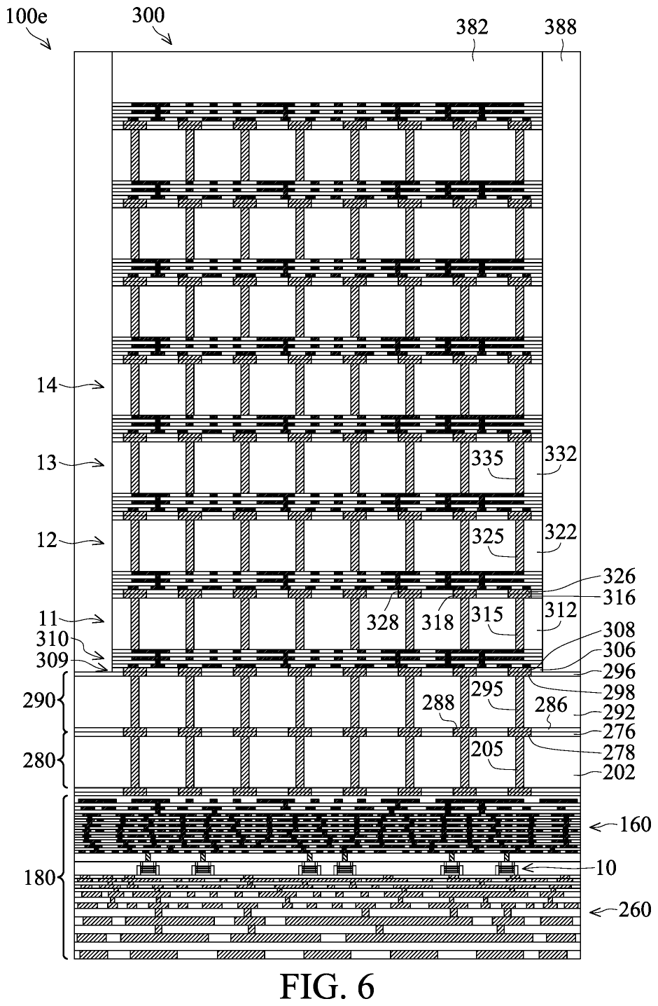

FIG. 6 shows a cross-sectional representation of a package structure 100e, in accordance with some embodiments of the disclosure. The package structure 100e is similar to, or the same as, the package structure 100a shown in FIGS. 3A-3G. Processes and materials used to form the semiconductor device structure 100e may be similar to, or the same as, those used to form the semiconductor device structure 100a and a detailed description thereof is not repeated herein.

The difference between FIG. 6 and FIG. 3H is that an interposer 290 is between the interposer 280 and the memory device 300. The interposer 290 may be similar to, or the same as, the interposer 280. The width of the interposer 290 may be the same as the width of the interposer 280. In some other embodiments, the width of the interposer 290 is smaller than the width of the interposer 280, and the width of the interposer 290 is the same as the width of the memory device 300.

The interposer 290 includes substrate 292, and TSV structures 295 formed in the substrate 292. The interposer 290 further includes the bonding layer 296 and conductive pads 298 embedded in the bonding layer 296, and the bonding layer 286 and conductive pads 288 embedded in the bonding layer 286. The bonding layer 296 is formed on front-side of the TSV structures 295, and the bonding layer 286 is formed on the back-side of the TSV structures 295. The interposer 290 is bonded to the interposer 280 by the hybrid bonding structure with the bonding layer 276 bonded to the bonding layer 286, and the conductive pads 278 bonded to the conductive pads 288. The interposer 290 is bonded to the memory device 300 by the hybrid bonding structure. The hybrid bonding structure is formed by bonding the bonding layer 296 to the bonding layer 306, and conductive pads 298 to the conductive pads 308.

In some embodiments, the passive devices (not shown) are formed in the substrate 292 of the interposer 290. The passive devices may be capacitors, inductors, resistors, or the like. In some embodiments, the active devices (not shown) are formed in the substrate 292 of the interposer 290. The active devices may be transistors, diodes, or the like.

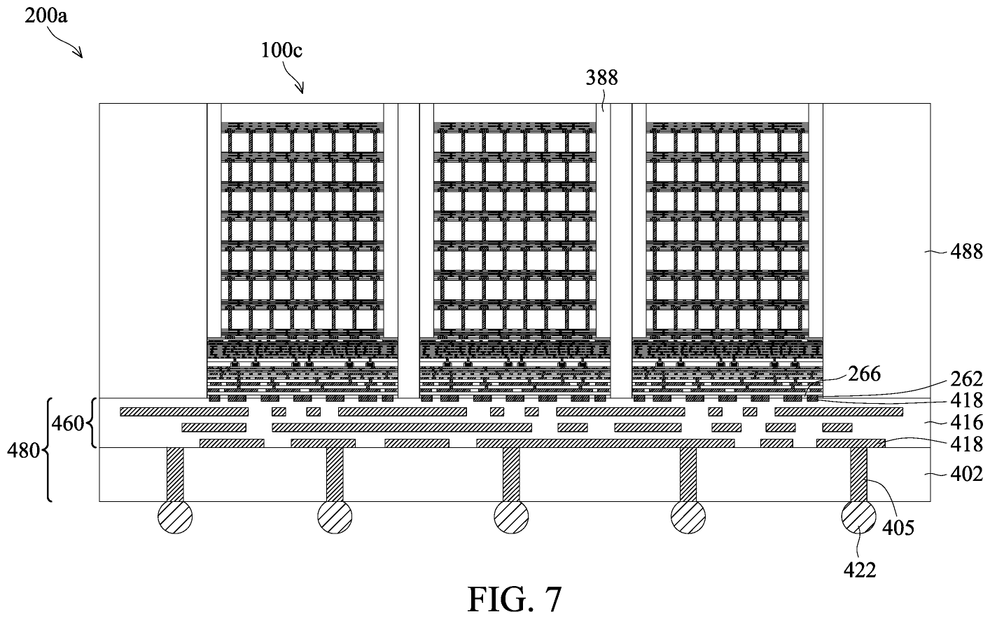

FIG. 7 shows a cross-sectional representation of a package structure 200a, in accordance with some embodiments of the disclosure. The package structure 100c is formed on the interposer 480. The package structure 100c can be replaced with the package structure 100a, 100b, 100d or 100e. The package structure 100a is shown in FIGS. 3A-3H, and the package structure 100b is shown in FIG. 3H′. The package structure 100c is shown in FIGS. 4A-4F, the package structure 100d is shown in FIG. 5, and the package structure 100e is shown in FIG. 6.

The interposer 480 includes a substrate 402, and TSV structures 405 embedded in the substrate 402, and an interconnect structure 460 formed on the substrate 402. In addition, the conductive connectors 422 are formed below the TSV structures 405. The interconnect structure 460 includes conducive layers 418 formed in the dielectric layer 416.

The package structure 100c is bonded to the interposer 480 by the hybrid bonding structure. The hybrid bonding structure includes metal-to-metal bonding and non-metal-to-non-metal bonding. The hybrid bonding structure includes conductive layers 418 bonded to the conductive layers 262, and dielectric layer 416 bonded to the dielectric layer 266.

In some embodiments, the conductive layers 418 are made of conductive materials, such as copper (Cu), copper alloy, aluminum (Al), aluminum alloys, combinations thereof or another applicable material. In some embodiments, the conductive layers 418 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition process.

The dielectric layer 416 may include multilayers made of multiple dielectric materials, such as silicon oxide, silicon nitride, silicon oxynitride, and/or other applicable dielectric materials. The dielectric layer 416 may be formed by chemical vapor deposition (CVD), physical vapor deposition, (PVD), atomic layer deposition (ALD), or other applicable processes.

The conductive connector 422 may be made of copper, a copper alloy, or another suitable material. In some embodiments, the conductive connectors 422 are formed by electroplating, electroless plating, printing, a chemical vapor deposition (CVD) process, a physical vapor process, or another applicable process.

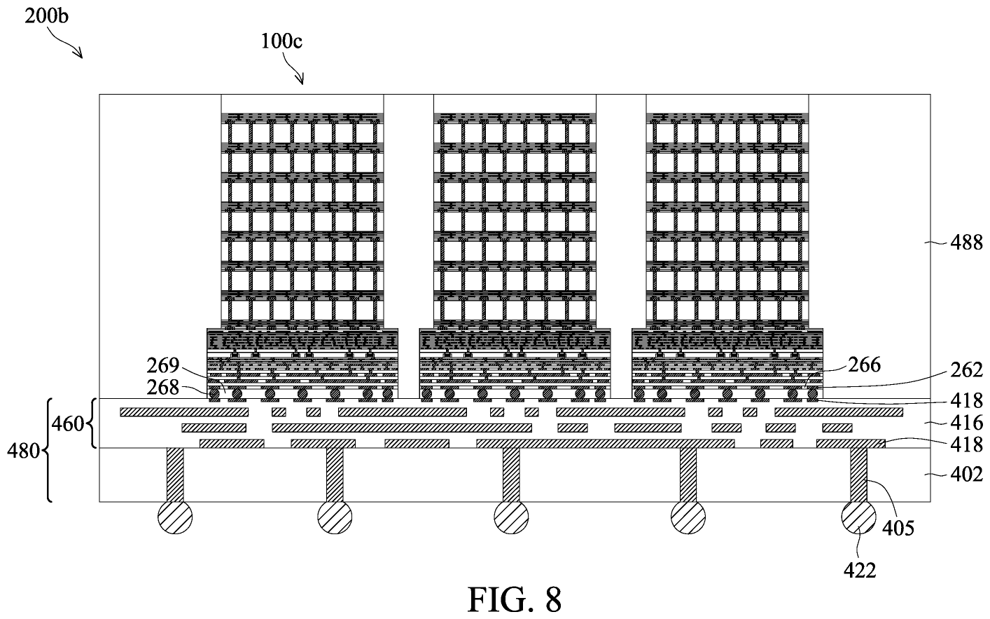

FIG. 8 shows a cross-sectional representation of a package structure 200b, in accordance with some embodiments of the disclosure. The package structure 200b is similar to, or the same as, the package structure 200a shown in FIG. 7. Processes and materials used to form the semiconductor device structure 200b may be similar to, or the same as, those used to form the semiconductor device structure 200a and a detailed description thereof is not repeated herein.

The difference between FIG. 8 and FIG. 7 is that the package structure 100c is formed on the interposer 480 by conductive connector 268 bonding process. The conductive connectors 268 are formed below the interconnect structure 260, and the conductive connectors 268 are surrounded by an underfill layer 269. In addition, the package layer 488 is in direct contact with the memory device 300, and no other package layer between the memory device 300 and the package layer 488.

In some embodiments, the underfill layer 269 includes an epoxy-based resin with fillers dispersed therein. The fillers may include insulating fibers, insulating particles, other suitable elements, or a combination thereof.

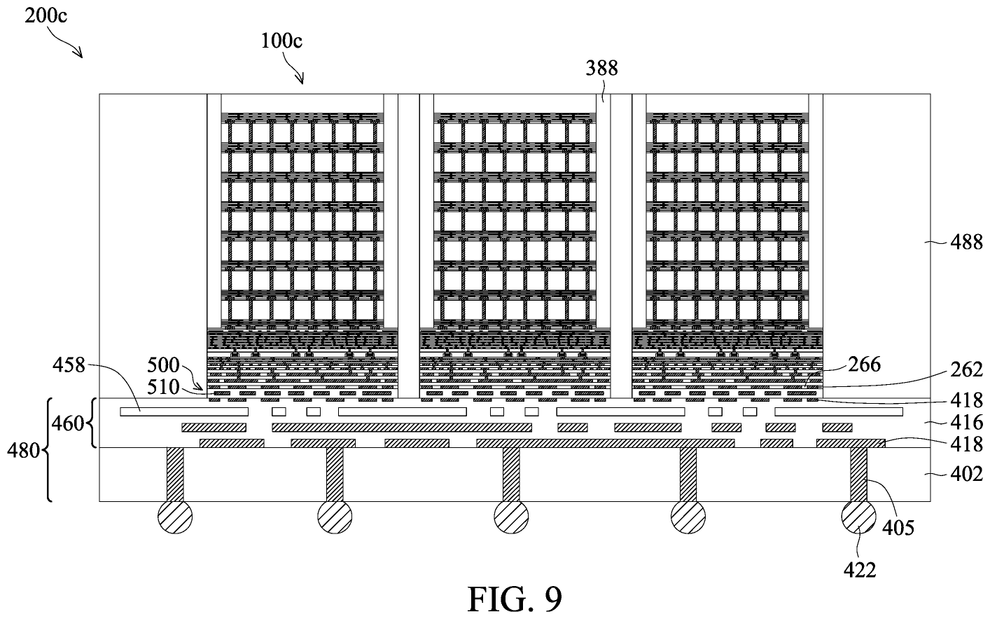

FIG. 9 shows a cross-sectional representation of a package structure 200c, in accordance with some embodiments of the disclosure. The package structure 200c is similar to, or the same as, the package structure 200a shown in FIG. 7. Processes and materials used to form the semiconductor device structure 200c may be similar to, or the same as, those used to form the semiconductor device structure 200a and a detailed description thereof is not repeated herein.

The difference between FIG. 9 and FIG. 7 is that an optical device 500 is formed below the logic device 10 and the memory device 300, the interconnect structure 160 and the interconnect structure 260. The waveguides 458 are formed in the interconnect structure 460 of the interposer 480. The optical device 500 facilitate the input/output (I/O) of optical signals to and from the waveguides 458. In some embodiments, the optical waveguides 458 includes ridge waveguides, rib waveguides, buried channel waveguides, diffused waveguides, slab waveguides etc.

The optical device 500 includes optical components 510. In some embodiments, the silicon layer (not shown) is patterned to form optical components 510, in accordance with some embodiments. The various optical components 510 are used to form a photonic integrated circuit (PIC). The optical components 510 include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

The optical components 510 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the outer sidewall surface of the optical device 500 extends beyond the outer sidewall surface of the memory device 300. The outer sidewall surface of the optical device 500 is substantially aligned with the outer sidewall surface of the electrical die 180.

If the optical device is formed on another package structure, which is adjacent to the package structure 100c, the optical passage of the optical device is increased. It should be noted that the optical device 500 is a part of the package structure 100c, and the optical device 500, the memory device 300 and the logic device 10 are combined within the package structure 100c. The signal of the memory device 300 can transfer to the logic device 10 through the interconnect structure 160 and the signal of the logic device 10 can directly transfer to the optical device 500 through the interconnect structure 260. The optical device 500 is directly below the logic device 10, rather than on another chip adjacent to the package structure 100c, the passage of the electrical signals and the optical signals are further reduced. Therefore, the optical signal transmission speed is further improved by forming the optical device 500 directly below the memory device 300 and the logic device 10.

In addition, since the optical device 500, the memory device 300 and the logic device 10 are combined within the package structure 100c, the light loss is reduced, and the light efficiency is greatly improved.

Furthermore, since the distance between the optical components 510 of the optical device 500 and the optical waveguides 458 of the interconnect structure 460 of the interposer 480 is greatly reduced, the coupling efficiency is greatly improved.

It should be noted that since the optical device 500 is formed below the login device 10 and the memory device 300, and the passage of the electrical signals and the optical signals are reduced and the transmission speed of the electrical signals and the optical signals are improved.

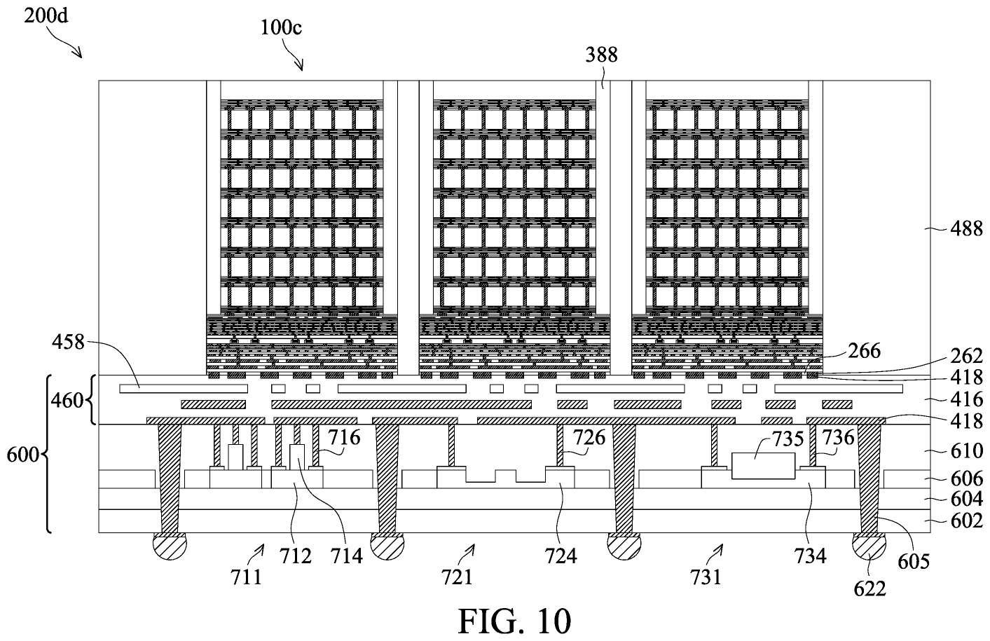

FIG. 10 shows a cross-sectional representation of a package structure 200d, in accordance with some embodiments of the disclosure. The package structure 200d is similar to, or the same as, the package structure 200a shown in FIG. 7. Processes and materials used to form the semiconductor device structure 200c may be similar to, or the same as, those used to form the semiconductor device structure 200a and a detailed description thereof is not repeated herein.

The package structure 100b is formed on the interposer 600. The package structure 100c can be replaced with the package structure 100a, 100b, 100d or 100e. The package structure 100a is shown in FIGS. 3A-3H, and the package structure 100b is shown in FIG. 3H′. The package structure 100c is shown in FIGS. 4A-4F. The package structure 100d is shown in FIG. 5, and the package structure 100e is shown in FIG. 6.

The interposer 600 includes a first semiconductor substrate 602, an oxide layer 604, a second semiconductor substrate 606, and a dielectric layer 610. In addition, the TSV structures 605 through the dielectric layer 610, the second semiconductor substrate 606, the oxide layer 604 and the first semiconductor substrate 602. The silicon-on-insulator (SOI) substrate is constructed by the first semiconductor substrate 602, the oxide layer 604, and the second semiconductor substrate 606. The interconnect structure 460 is formed on the dielectric layer 610. In addition, the conductive connectors 622 are formed below the TSV structures 605.

The first device 711, a second device 721 and a third device 731 are formed in the second semiconductor substrate 606 and the dielectric layer 610. In some embodiments, the first device 711 is transistors. The transistor includes gate structure 714 formed on the well region 712, and an S/D structure (not shown) formed in the well region 14. The S/D structure is electrical

ly connected to the conductive layers 418 by the contact structure 716. In addition, the gate structure 714 is electrically connected to the conductive layers 418 by the contact structure 716.

In some embodiments, the second device 721 is an optical device, such as modulator. The modulator may include a P-N modulator, which is formed by performing one or more implantation processes to introduce dopants within the silicon layer 724 after the patterning of the silicon layer 724. The silicon layer 724 may be doped with p-type dopants, n-type dopants, or a combination. The contact structure 726 is electrically connected to the silicon layer 724.

In some embodiments, the third device 731 is an optical device, such as photo detector. The photo detector may be germanium (Ge) modulator. The germanium modulator may be formed by, for example, partially etching regions of the silicon layer 734 and growing an epitaxial material 735 on the remaining silicon of the etched regions. The silicon layer 734 may be etched using acceptable photolithography and etching techniques. The epitaxial material may comprise, for example, a semiconductor material such as germanium (Ge), which may be doped or undoped. The contact structure 736 is electrically connected to the silicon layer 734.

The optical devices, such as the second device 721 or the third device 731, facilitates the input/output (I/O) of optical signals to and from the waveguides 458. The optical devices, such as the second device 721 or the third device 731, are formed over the SOI substrate. The optical signal can be transferred from the second device 721 or the third device 731 to the waveguides 458, or transferred from the waveguides 458 to the second device 721 or the third device 731.

The electrical signal of the semiconductor structure 10 can be transferred from the interconnect structure 160 or the interconnect structure 260. Since the signals can be transferred from the semiconductor structure 10 to the front-side and back-side of the substrate 202, the I/O numbers can be increased. As a result, the bandwidth of the package structure 100a can be increased.

The memory device 300 and the electrical die 180 with the logic device 10 are stacked vertically, rather than horizontally, the passage of the electrical signals is reduced and the transmission speed of the electrical signals is improved. In addition, the interposer 280 and/or interposer 290 is between the memory device 300 and electrical die 180 for help the signal transmission.

The electrical signals of the memory device 300 and the logic device 10 of the package structure 100a, 100b, 100d or 100e can be transferred to the optical devices (such as waveguides 458) in the interposer 600. In other words, the optical signal of the interposer 600 can be transferred to the memory device 300 and the logic device 10 of the package structure 100a, 100b, 100d or 100e.

The package structure 100a, 100b, 100d or 100e is directly formed on the interposer 600 with the optical devices, and therefore the electrical signals of the memory device 300 and the logic device 10 can be transferred to the interposer 600 by the front-side interconnect structure 160 and/or the back-side interconnect structure 260. That is, the interposer 600 with the optical devices is directly below the memory device 300 and the logic device 10, rather than on another chip adjacent to the package structure 100c, the passage of the electrical signals and the optical signals are further reduced. Therefore, the optical signal transmission speed is further improved by forming the interposer 600 with the optical devices directly below the memory device 300 and the logic device 10.

Furthermore, since the distance between the optical devices (the second device 721 may be modulator, and the third device 731 may be the photo detector) and the optical waveguides 458 is greatly reduced, the coupling efficiency is greatly improved.

The package structures 100a, 100b, 100c, 100d and 100e can be sawed from a wafer, and can be bonded to the interposer 480. In addition, the interposer 480 includes optical devices. Therefore, the optical device 500, the second device 21 or the third device 31 can help the transmission of the optical signals.

Embodiments for forming a package structure and method for formation the same are provided. The electrical die includes a substrate, and a logic device formed on the substrate, and the front-side interconnect structure and the back-side interconnect structure formed on opposite sidewall surfaces of the substrate. The memory device is formed on the electrical die with logic device. Since the memory device is vertically formed on the electrical die, the passage of the electrical signals is reduced and the transmission speed of the electrical signals is improved. When the signal path is reduced, the driving power for the package structure can be reduced. Therefore, the power efficiency of the package structure is increased. Furthermore, since the optical device is formed below the login device and the memory device, and the passage of the electrical signals and the optical signals are reduced and the transmission speed of the electrical signals and the optical signals are improved.

In some embodiments, a package structure is provided. The package structure includes a semiconductor device formed over a substrate, and a first interconnect structure formed over the semiconductor device. The package structure includes a second interconnect structure formed below the semiconductor device, and a memory device formed over the first interconnect structure. The package structure includes a hybrid bonding structure between the first interconnect structure and the memory device.

In some embodiments, a package structure is provided. The package structure includes a first die formed over an interposer, and the first die includes a first logic device, a first memory device formed over the first logic device, and a hybrid bonding structure between the first logic device and the first memory device. The package structure includes a second die adjacent to the first die. The second die includes a second logic device, and a second memory device formed over the second logic device; and a package layer surrounding the first die and the second die. A portion of the interposer is covered by the package layer.

In some embodiments, a method for forming a package structure is provided. The method includes forming a logic device over a substrate, and forming a first interconnect structure on a front-side surface of the logic device. The method includes forming a second interconnect structure on a back-side surface of the logic device, and bonding a memory device on the first interconnect structure by a hybrid bonding structure to form a die. The hybrid bonding structure includes a metal-to-metal bonding and a non-metal-to-non-metal bonding.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a semiconductor device over a substrate;
a first interconnect structure formed over the semiconductor device;
a second interconnect structure formed below the semiconductor device;
a memory device formed over the first interconnect structure, wherein the memory device comprises a plurality of memory dies; and
a hybrid bonding structure between the first interconnect structure and the memory device, wherein an outer sidewall surface of the first interconnect structure extends beyond an outer sidewall surface of one of the memory dies.

2. The package structure as claimed in claim 1, further comprising:
a first interposer between the first interconnect structure and the memory device, wherein the first interposer includes through-substrate via (TSV) structures.

3. The package structure as claimed in claim 2, further comprising:
a second interposer formed on the first interposer, wherein the second interposer is in direct contact with the memory device.

4. The package structure as claimed in claim 2, wherein the outer sidewall surface of the first interconnect structure extends beyond an outer sidewall surface of the first interposer.

5. The package structure as claimed in claim 1, wherein each of the memory dies comprises a plurality of through substrate via (TSV) structures.

6. The package structure as claimed in claim 1, further comprising:
a package layer formed on the substrate, wherein the memory device is surrounded by the package layer.

7. The package structure as claimed in claim 1, further comprising:
an optical device formed below the second interconnect structure, wherein the optical device comprises an optical component.

8. The package structure as claimed in claim 1, wherein the semiconductor device comprises:
nanostructures formed over the substrate;
an S/D structure connected to the nanostructures;
a gate structure wrapped around the nanostructures; and
an inner space layer between the gate structure and the S/D structure.

9. The package structure as claimed in claim 1, wherein the substrate comprises:
a first semiconductor substrate;
an oxide layer;
a second semiconductor substrate; and
a plurality of through substrate via (TSV) structures through the first semiconductor substrate and the second semiconductor substrate.

10. A package structure, comprising:
a first die formed over an interposer, wherein the first die comprises:
a first logic device;
a first memory device formed over the first logic device; and
a hybrid bonding structure between the first logic device and the first memory device;
a second die adjacent to the first die, wherein the second die comprises:
a second logic device; and
a second memory device formed over the second logic device; and
a package layer surrounding the first die and the second die, wherein a portion of the interposer is covered by the package layer.

11. The package structure as claimed in claim 10, further comprising:
a back-side interconnect structure formed below the first logic device, wherein the first memory device and the back-side interconnect structure formed on opposite sidewall surfaces of the first logic device.

12. The package structure as claimed in claim 10, wherein the interposer comprises a plurality of through substrate via (TSV) structures and a plurality of conductive layers over the TSV structures.

13. The package structure as claimed in claim 12, wherein the interposer further comprises a plurality of optical devices between the TSV structures.

14. The package structure as claimed in claim 10, wherein the first die further comprises an optical device, wherein an outer sidewall surface of the optical device extends beyond an outer sidewall surface of the first memory device.

15. The package structure as claimed in claim 10, wherein the interposer comprises:
a first semiconductor substrate;
an oxide layer;
a second semiconductor substrate; and
a plurality of through substrate via (TSV) structures through the first semiconductor substrate and the second semiconductor substrate.

16. The package structure as claimed in claim 10, wherein the interposer further comprises a waveguide.

17. A method for forming a package structure, comprising:
forming a logic device over a substrate;
forming a first interconnect structure on a front-side surface of the logic device;
forming a second interconnect structure on a back-side surface of the logic device; and
bonding a memory device on the first interconnect structure by a hybrid bonding structure to form a die, wherein the hybrid bonding structure includes a metal-to-metal bonding and a non-metal-to-non-metal bonding.

18. The method for forming the package structure as claimed in claim 17, further comprising:
bonding the die to an interposer, wherein the interposer is below the second interconnect structure; and
forming a package layer surrounding the memory device.

19. The method for forming the package structure as claimed in claim 17, further comprising:
forming an optical device below the second interconnect structure.

20. The method for forming the package structure as claimed in claim 17, wherein the substrate comprises:
a first semiconductor substrate;
an oxide layer;
a second semiconductor substrate; and
a plurality of through substrate via (TSV) structures through the first semiconductor substrate and the second semiconductor substrate.
